(19) United States
(12) Patent Application Publication
(10) Pub. No.: US 2026/0155822 A1
(43) Pub. Date: Jun. 4, 2026

(54) GATE DRIVER POWER SUPPLIES

(71) Applicant: The Johns Hopkins University, Baltimore, MD (US)

(72) Inventors: Joseph P. Kozak, Washington, DC (US); Juan D. Ramirez, Hyattsville, MD (US); Andrew C. Baisden, Rockville, MD (US)

(21) Appl. No.: 19/345,121

(22) Filed: Sep. 30, 2025

Related U.S. Application Data
(60) Provisional application No. 63/727,913, filed on Dec. 4, 2024.

(51) Int. Cl. H03K 17/687; H02M 1/00; H02M 1/088; H02M 3/158

(52) U.S. Cl. CPC H03K 17/6871; H02M 1/0045; H02M 1/088; H02M 3/158; H03K 2217/0027; H03K 2217/0063; H03K 2217/0072; H03K 2217/0081

(57) ABSTRACT

In one embodiment, a system for supplying power includes a gate driver power supply configured to receive an input voltage from a power source and to change between a first state of operation, in which the gate driver power supply receives an input voltage having a voltage value from the power source and the gate driver power supply outputs a first output voltage, and a second state of operation, in which the gate driver power supply receives the input voltage having the voltage value from the power source and the gate driver power supply outputs a second output voltage, the second output voltage being different than the first output voltage.

### CROSS REFERENCE TO RELATED APPLICATIONS

The present application claims priority to U.S. Provisional Patent Application No. 63/727,913 entitled “Adaptive, Multi-Output, Isolated DC/DC Converter For Inverter Gate Driver Applications” filed on Dec. 4, 2024, which is hereby incorporated by reference in its entirety.

### FIELD

The present disclosure generally relates to gate driver power supplies.

### BACKGROUND

One of the staple elements of power electronic converters is the gate driver network and gate driver power supply. For power electronic converters, the power transistor requires an auxiliary power source and control signal to control the transition between the blocking and conducting modes. With the integration of new wide bandgap (WBG) power semiconductor devices to power converters, in particular silicon carbide (SiC) metal-oxide-semiconductor field-effect transistors (MOSFETs), many new methodologies have been proposed for more efficient and reliable switching. To integrate SiC MOSFETs into high-reliability, aerospace applications, the gate and drain voltages must be derated to minimize the overall electrical stress on the device and excite various failure mechanisms. The EEE-INST-002 standard, which is used for many deep-space, high-reliability aerospace missions, has devices derated to 60% of the rated gate-source voltage (V_{GS}). With SiC MOSFETs, this can significantly limit performance as the on-resistance (R_{DSon}) can vary between the derated and manufacturer-rated gate voltages.

### SUMMARY

In one aspect, a system for supplying power is provided that in one embodiment includes a gate driver power supply configured to receive an input voltage from a power source and to change between a first state of operation, in which the gate driver power supply receives an input voltage having a voltage value from the power source and the gate driver power supply outputs a first output voltage, and a second state of operation, in which the gate driver power supply receives the input voltage having the voltage value from the power source and the gate driver power supply outputs a second output voltage. The second output voltage is different than the first output voltage. The gate driver power supply includes a controller. The controller is configured to compare a reference current data value with a current data value indicating a current in a power circuit and to, based on the comparison, cause the gate driver power supply to change from one of the first state of operation and the second state of operation to the other of the first state of operation and the second state of operation.

The system can vary in one or more ways. For example, the first output voltage can be a rated voltage, the second output voltage can be a derated voltage, the controller can be further configured to cause the gate driver power supply to change from the first state of operation to the second state of operation based on the current data value being less than the reference current data value, and the controller can be further configured to cause the gate driver power supply to change from the second state of operation to the first state of operation based on the current data value being greater than the reference current data value.

For another example, the system can also include the power source.

For yet another example, the gate driver power supply can also include a linear voltage regulator configured to receive the input voltage, and a push-pull converter in-line with the linear voltage regulator. Further, the controller being configured to cause the gate driver power supply to change from the one of the first state of operation and the second state of operation to the other of the first state of operation and the second state of operation based on the comparison can include causing a bias of the linear voltage regulator to change.

For yet another example, the power circuit can include a first power transistor including silicon carbide and a second power transistor including silicon carbide.

For still another example, the system can also include a current sensor configured to measure the input current. Further, the power circuit can include the current sensor.

In another embodiment, a system for supplying power includes a current sensor configured to measure a current in a power circuit, and a gate driver power supply configured to output an output voltage. The gate driver power supply includes a linear voltage regulator configured to receive a voltage input to the gate driver power supply from the power source, a push-pull converter in-line with the linear voltage regulator, and a controller. The controller is configured to compare a reference current data value with a current data value indicating the measured current and to, based on the comparison, cause the gate driver power supply to change the output voltage.

The system can vary in one or more ways. For example, the output voltage can be one of: a rated voltage or a derated voltage.

For example, the controller can be further configured to cause the gate driver power supply to change from outputting a first output voltage to outputting a second, different output voltage based on the measured current data value being less than the reference current data value. Further, the controller can be further configured to, based on the comparison indicating the measured current data value being greater than the reference current data value, cause the gate driver power supply to change from outputting the second output voltage to outputting the first output voltage.

For another example, the power circuit can include a first power transistor comprising silicon carbide and a second power transistor comprising silicon carbide. Further, the power circuit can include the current sensor.

For still another example, the system can include the power source.

In another aspect, a method for supplying power is provided that in one embodiment includes determining, at a gate driver power supply, whether a current data value indicating a current in a power circuit is less than or greater than a reference current value, and, if the current data value is determined to be less than the reference current value, causing the gate driver power supply to output a derated output voltage. The method also includes, if the current data value is determined to be greater than the reference current value, causing the gate driver power supply to output a rated output voltage.

The method can vary in one or more ways. For example, the method can also include measuring, at the power circuit, the current in the power circuit. Further, the power circuit can include a current sensor that measures the current in the power circuit.

For another example, a current sensor can measure the current, a linear voltage regulator of the gate driver power supply can receive a voltage input to the gate driver power supply from a power source, a push-pull converter of the gate driver power supply can be in-line with the linear voltage regulator, and a controller can be configured to perform the determining, the causing to output the derated output voltage, and the causing to output the rated output voltage. Further, the power circuit can include the current sensor.

For yet another example, the method can further include receiving, at the gate driver power supply, power from a power source, and the determining, the causing of the gate driver power supply to output the derated output voltage, and the causing of the gate driver power supply to output the rated output voltage can occur with the gate driver power supply receiving the power from the power source.

### BRIEF DESCRIPTION OF DRAWINGS

FIG. 1 is a circuit diagram of one embodiment of a half bridge power circuit including various alternative gate driver circuit configurations;

FIG. 2 is a schematic view of one embodiment of a system including a gate driver power supply and a power source;

FIG. 3 is a circuit diagram of one embodiment of a gate driver power supply;

FIG. 4 is a perspective view of one embodiment of a system including a gate driver power supply and a synchronous buck converter;

FIG. 5A is a graph showing measured efficiency and high-side transistor case temperature of the synchronous buck converter of FIG. 4 operating at varying switching frequencies, different V_{GS} values, and 5 A output current;

FIG. 5B is a graph showing measured efficiency and high-side transistor case temperature of the synchronous buck converter of FIG. 4 operating at varying switching frequencies, different V_{GS} values, and 10 A output current;

FIG. 6 is a graph showing a startup sequence of the gate driver power supply of FIG. 4 when primary power was applied to the input voltage rail and output voltage was monitored to be 11.4 V;

FIG. 7A is a graph showing output waveforms of the gate driver power supply of FIG. 4 from a transition from a low-output state to a high-output state;

FIG. 7B is a graph showing output waveforms of the gate driver power supply of FIG. 4 from a transition from the high-output state down to the low-output state.

FIG. 8A is a graph showing output waveforms for the synchronous buck converter of FIG. 4 operating at 100 kHz when load current was below a current trigger and V_{GS} equaled 11 V;

FIG. 8B is a graph showing output waveforms for the synchronous buck converter of FIG. 4 operating at 100 kHz when the load current was above the current trigger and V_{GS} equaled 15 V;

FIG. 9 is a flowchart showing one embodiment of a method for supplying power; and

FIG. 10 is a flowchart showing one embodiment of aspects of the method of FIG. 9.

Unless otherwise indicated, the drawings provided herein are meant to illustrate features of embodiments of this disclosure. These features are believed to be applicable in a wide variety of systems comprising one or more embodiments of this disclosure. As such, the drawings are not meant to include all conventional features known by those of ordinary skill in the art to be required for the practice of the embodiments disclosed herein.

### DETAILED DESCRIPTION

As discovered by the inventors, various illustrative devices, systems, and methods for gate driver power supplies are provided. Various applications, for example high-reliability aerospace applications, require strict derating of gate and drain biases on all power devices. As recognized by the inventors, with the integration of SiC MOSFETs, and with the integration of wide bandgap power devices in general, the derating protocols dramatically influence the electrical performance of power electronic circuits. In one or more embodiments described herein, a gate driver power supply (GDPS) configured as an active gate driver power supply (AGDPS) can be configured to provide a varied output voltage to a power device to meet both derating and high-performance operations. The AGDPS can be configured to produce two discrete output voltages, such as two discrete derated and rated output voltages. In this way, the power device can be configured to normally operate under a first, e.g., derated, voltage, but under high-performance, pulsed applications can be configured to operate at a second, e.g., rated, voltage. In some embodiments, overall reliability may therefore be achieved and electrical losses may be minimized when high-current outputs are necessary. The AGDPS may help ensure that the power device operates at the first, e.g., derated, value most of the time and up to the first value, e.g., terrestrially rated value, under high-performance instances.

In one or more embodiments described herein, any circuits used for altering an operating gate voltage of a GDPS can be located at the GDPS instead of at a gate driving network. As a result, this changes the need for additional analog circuitry in the gate driving network or after the GDPS, and a traditionally designed, multi-output power converter can be utilized. In one or more embodiments described herein, a GDPS can have multiple voltage outputs that can be configured to then be cascaded into the primary the primary transistor's gate driving network such that additional components to the driver circuitry are not added, and the operating V_{GS} can be adjusted based upon the operating conditions of the primary device. In some embodiments, the varied gate driving voltage can be provided by the GDPS using a linear regulator on the output or can be provided another way, such as using multiple output windings off of the transformer core or changing a duty cycle or switching frequency on a primary side of a DC/DC converter.

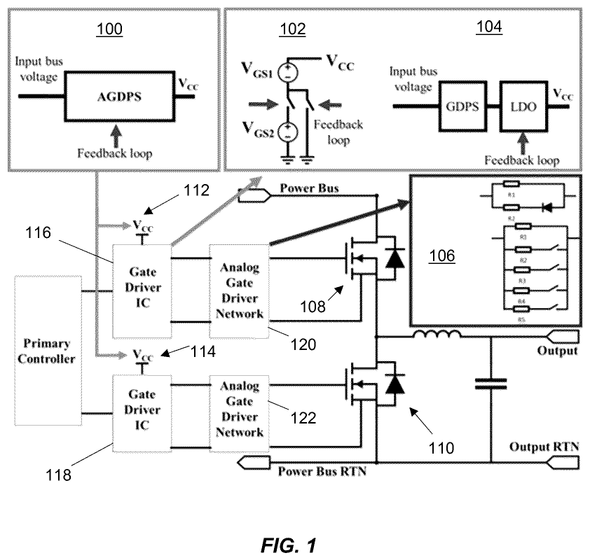

FIG. 1 illustrates an exemplary circuit diagram of a system 100 configured to provide a varied gate driving voltage to a power device to meet both derating and high-performance operations according to some embodiments. FIG. 1 also shows first, second, and third alternative methodologies 102, 104, 106 for comparison purposes. In some embodiments, as discovered by the inventors, the system 100 of FIG. 1 does not include the first, second, and third alternative methodologies 102, 104, 106 such that additional components to the driver circuitry are not added in the system 100.

As recognized by the inventors, adaptive gate driver networks can provide different voltage levels onto a primary switching device while focusing on increasing the efficiency of the power converter. These systems can be especially integrated for SiC MOSFETs because of the opportunity for faster switching events in comparison to traditional silicon devices. FIG. 1 showcases the first, second, and third alternative methodologies 102, 104, 106 implementing additional circuitry to develop the active gate driver network.

As recognized by the inventors, the two primary instances to develop an active gate driver network include introducing changes to the driving voltage value to the system's gate driver integrated circuit (IC) (which may also be referred to as a “current booster”) 116, 118, or changing the system's analog circuit network 120, 122 connecting to the primary device's gate terminal. With techniques that focus on changing the V_{CC} of the system, there are two particular methodologies to perform this. The first is a multi-voltage level network as shown for example in the first methodology 102. The methodologies such as the first methodology 102 utilize multiple (external) power supply voltages and connects them in series, but includes a switch to bypass the network. In this way, the voltage magnitude can be stepped up or down at different time intervals to not overdrive the voltage of the system overall. Additionally, different linear regulators can be used instead of the GDPS to tune the V_{CC} magnitude, as shown for example in the second methodology 104. The methodologies such as the second methodology 104 can include a feedback network that can be controlled from various factors including, for example, the input or output current, the device's operating temperature, or on-state resistance (R_{DSon}). Both of the first and second methodologies 102, 104 can provide additional circuitry (as compared to the system 100) on top of the baseline required GDPS to operate the primary power circuit. Finally, other methodologies, such as shown for example in the third methodology 106, can be used to change the driving voltage or current directly in the analog circuitry connecting the gate driver IC 116, 118 and the device's gate. Methodologies such as the third methodology 106 can primarily adjust the changes in the turn-on/off times based on the currents being sourced or sinked.

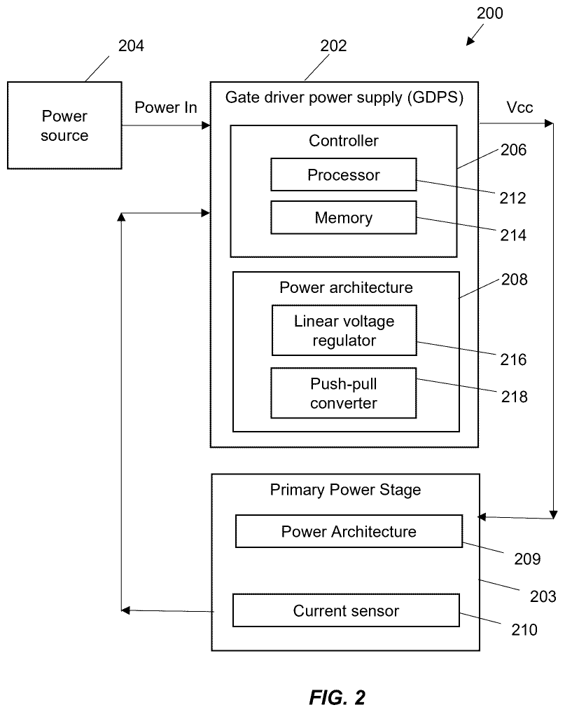

FIG. 2 illustrates an exemplary schematic view of a system 200 including a gate driver power supply (GDPS) 202, a primary power stage 203 configured to be communicatively coupled to the GDPS 202, and a power source 204 configured to supply power to the GDPS 202 according to some embodiments. The GDPS 202 can be configured as an AGDPS configured to provide a varied gate driving voltage to a power device, for example to meet both derated and high-performance operations. For example, MOSFET gate drivers in the primary power stage 203, e.g., in the power architecture 209, can receive a V_{CC} output of the GDPS 202.

As shown in this illustrated embodiment, the GDPS 202 can include a controller 206 and a power architecture 208, and the primary power stage 203 can include a power circuit (labeled as a “power architecture” in FIG. 2) 209 and a current sensor 210. As also shown in this illustrated embodiment, the controller 206 can include a processor 212 and a memory 214. The GDPS 202 and the primary power stage 203 can each include additional element(s) configured to facilitate use of the elements shown in FIG. 2, such as a plurality of any of these elements (e.g., one or more controllers, one or more memories, one or more current sensors, etc.), an exterior housing configured to house elements of the GDPS 202 and the primary power stage 203 shown in FIG. 2, a printed circuit board (PCB) or other board configured to facilitate mounting of electronic components, a bus configured to facilitate communication between electronic components, etc. The controller 206, the power architecture 208 of the GDPS 202, the power architecture 209 of the primary power stage 203, the current sensor 210, the processor 212, and the memory 214 are shown as separate elements in the embodiment of FIG. 2, as are the GDPS 202 and the primary power stage 203, but one or more of these elements can be combined. For example, the controller 206 and the current sensor 210 can together be part of a single microcontroller.

The processor 212 can be configured to execute operations in accordance with instructions stored in the memory 214. The processor 212 can also be configured to be in communication with the power source 204, the power architectures 208, 209, and the current sensor 210 to facilitate performance of various operations, as discussed further herein.

The current sensor 210 can be configured to measure an input current or an output current of the primary power stage 203. FIG. 2 illustrates the power source 204 being configured to provide a positive input voltage to the GDPS 202. The current sensor 210 can be configured to measure a current of the collector-side positive input voltage. In some embodiments, the current sensor 210 can be a hall effect sensor or other type of current sensor.

The power architectures 208, 209 can have a variety of configurations. As in this illustrated embodiment, the power architecture 208 of the GDPS 202 can include a linear voltage regulator 216 and a push-pull converter 218. As one of ordinary skill in the art will recognize, other configurations for the power architectures 208, 209 can be used. As discussed further herein, the controller 206 can be configured to control the power architecture 208 of the GDPS 202 based on the input current measured using the current sensor 210 to provide a varied output voltage. As in this illustrated embodiment, the controller 206 can be configured to control the push-pull converter 218 to change the driving voltage directly from the GDPS 202.

The system 200 can be configured to be used in various applications that require strict derating of gate and drain biases on all power devices. One example of applications requiring strict derating of gate and drain biases on all power devices is high-reliability aerospace applications.

High-reliability aerospace applications require strict derating of both drain and gate biases to ensure overall lifetime and reliability of power transistors. These standards have been primarily driven as a result of combined radiation and electrical stressors observed in traditional silicon transistors. One of the most common standards, EEE-INST-002, instructs that MOSFETs, such as first and second MOSFETs 108, 110 shown in the example of FIG. 1, be derated to 75% the drain-source voltage (V_{DS}) rating, and 60% the rated Vos. Additionally, the junction temperature of the device is another factor that requires derating; for MOSFETs the standard requires to adhere to 80 deg C or 75% the maximum junction temperature (whichever is lower). These ratings greatly impact the performance capabilities of newer devices like SiC MOSFETs which have a higher junction temperature rating (and higher thermal conductivity), as well as more variability in the R_{DSon} between on-state driving V_{GS} magnitudes.

Since these standards were derived from years of data acquired on silicon devices, the impact of the derating can lead to drastic changes in the operating conditions for new devices. For the aforementioned SiC MOSFETs, derated values can have a 50% R_{DSon} increase in comparison to the rated voltage. Additionally, SiC device manufacturers can include both static and transient ratings. Overall, the variance in which V_{GS} magnitudes drive the device for derating purposes can cause design tension between maximizing electrical performance and reliability for future aerospace missions. Since newer aerospace applications, such as the NASA Dragonfly mission, apply a high-current through the semiconductor device, a realization to allow the device to operate closer to terrestrial applications has been made, and the derating has been applied to the transient V_{GS} rating. However, operating at this derated state still introduces losses that are higher than those seen in terrestrial applications.

Equations 1 and 2 show overall losses within a transistor, such as first and second transistors of the power circuit 209 shown in the example of FIG. 2, operating in a power converter (conduction and switching losses), and that the conduction losses are equal to the conduction current (ID) squared, multiplied by the R_{DSon}, and duty cycle.

$${P}_{loss} = {P}_{con} + {P}_{sw} \qquad ( 1 )$$

$${P}_{con} = {I}_{D}^{2} * {R}_{DSon} * D \qquad ( 2 )$$

To fully demonstrate the value of the AGDPSs described herein, and determine the feedback point where the output Vos magnitude is increased, losses for a primary SiC MOSFET with a 650 V, 16 A rating (C3M0120065K) were analyzed.

As mentioned above, many SiC manufacturers now include both a dynamic and static rating; this device can have, for example, a dynamic rated gate-voltage of 19 V and a static rated gate-voltage of 15 V. Since standards currently do not exist for SiC-based devices, a comparison of the derated values for both ratings was initially considered. With the standard gate-voltage rating (15 V) the resulting derated voltage would be 9 V, and for the transient gate-voltage rating (19 V) the derated value would be 11.4 V. The reported output characteristics on the SiC MOSFET with a 650 V, 16 A rating (C3M0120065K) datasheet were examined such that the R_{DSon} values could be extracted based upon load-current, and gate voltage. Table 1 shows the extracted values for VDs across the device for different load currents from the datasheet. More particularly, Table 1 shows extracted electrical characteristics, normalized R_{DSon}, and calculated power losses for the selected device under test at 25° C. R_{DSon} was then calculated, and normalized in comparison to the lowest value (when V_{GS}=15 V). The conduction losses, as expressed by Equation (2) was then calculated. As can be seen in Table 1, at lower conduction currents the loss difference for the chosen device is much smaller (less than 1 W); however, when the conduction current increases, the losses increase to single digit, or greater than ten Watts of power. Additionally, while the switching losses are impactful in the overall operation of the design, and do change with respect to operating voltage and current ratings, a full analysis for these losses was not considered as the operating point for aerospace applications will normally have P_{con} to be greater than P_{sw}.

TABLE 1

| V_{GS} (V) | V_{DS} (V) | I_{D} (A) | R_{DSon} (Ω) | R_{DSon} norm | P_{con} (W) |
|---|---|---|---|---|---|
| 9 | 1.6 | 5 | 0.32 | 2.13 | 4 |
| 11 | 1 | 5 | 0.2 | 1.33 | 2.5 |
| 13 | 0.8 | 5 | 0.16 | 1.07 | 2 |
| 15 | 0.75 | 5 | 0.15 | 1 | 1.875 |
| 9 | 3.25 | 10 | 0.325 | 2.6 | 16.25 |
| 11 | 1.9 | 10 | 0.19 | 1.52 | 9.5 |
| 13 | 1.5 | 10 | 0.15 | 1.2 | 7.5 |
| 15 | 1.25 | 10 | 0.125 | 1 | 6.25 |
| 9 | N/A | 20 | N/A | N/A | N/A |
| 11 | 4.1 | 20 | 0.205 | 1.64 | 41 |
| 13 | 3 | 20 | 0.15 | 1.2 | 30 |
| 15 | 2.5 | 20 | 0.125 | 1 | 25 |

As a result of this analysis, the outputs of the AGDPS were selected to output 15 V for the high value to match the manufacturer rated voltage, and 11 V as the low value to meet the derating guidelines.

The voltage values in Table 1 are examples that can be appropriate for some applications, such as aerospace applications in which input voltage can be in a range of 70 V to 100 V. In other applications, input voltage values may be different, such as electric vehicle applications in which input voltage can be in a range of 400 V to 800 V, and thus different voltage values than those shown in Table 1 can be used.

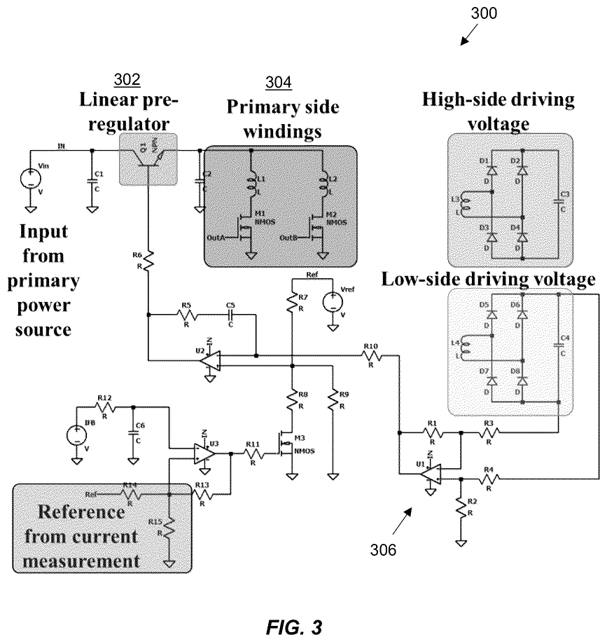

Referring now to FIG. 3, FIG. 3 illustrates an exemplary circuit diagram of the GDPS 202 of FIG. 2 as a GDPS 300 according to some embodiments. As shown, a linear voltage regulator 302 of the GDPS 300 can be configured to feed an open-loop, push-pull converter 304 with single winding secondary outputs and bridge rectifiers. The GDPS 300 can thus include a push-pull converter 304 with linear pre-regulator 302 that incorporates a feedback reference which is configured to be determined by the current measurement of a primary power circuit, such as the power circuit 209 of FIG. 2. As also shown in FIG. 3, the GDPS 300 can include a difference amplifier 306 configured to sense a low-side output (to the half-bridge low-side device), as a feedback to the linear regulator 302. One embodiment of design parameters of the GDPS 300 of FIG. 3 is shown in Table 2.

TABLE 2

| General Parameters | Value | |
|---|---|---|
| Input Voltage | 12 | V |
| Switching Frequency | 200 | kHz |
| Output Voltage | 15 V and 11 V | |
| Max load current | 20 | mA |
| Transformer Design | | |
| Turns Ratio | 1:1:1.5:1.5 | |
| Max primary RMS current | 50 | mA |
| Min magnetizing inductance | 100 | μH |
| Input Filter | | |
| Attenuation at 200 kHz | 60 | dB |
| Max output impedance | 1.5 | Ohm |

To control the magnitude of the output of the GDPS 300 of FIG. 3, a feedback loop can be integrated with the primary power circuit (not shown in FIG. 3). While multiple types of current measurements techniques can be utilized in this methodology, a hall effect sensor can be used, as in this illustrated embodiment, to measure an average input current of the power converter 304. This current can be compared to a reference point, which can change a bias of the linear regulator 302 in-line with the push-pull topology 304. Once the current reaches a determined threshold, the gate driver power supply 300 can be configured to alter the output voltage to increase the gate voltage. In some embodiments, this may result in decreasing the on-resistance and minimizing the overall system losses. A hysteresis control for this shift can be included such that the voltage change only occurs when the GDPS's conducted current is maintained above the determined threshold for a significant period of time. The resulting circuit details are expressed for one embodiment shown in Table 2.

The parameters of the embodiment of Table 2 include a 12 V input, which can be taken, for example, from one of the primary buses in aerospace applications. The primary transformer, as detailed in Table 2, includes multiple taps on the secondary for both the high-side and low-side driving voltages. The transition from the 11 V to the 15 V output was selected in this embodiment to be conducted at around a 10 A output to best demonstrate the increase in performance of the driven power SiC MOSFET.

The parameters shown in Table 2 are examples that can be appropriate for some applications, such as aerospace applications in which input voltage can be in a range of 70 V to 100 V. In other applications, input voltage values may be different, such as electric vehicle applications in which input voltage can be in a range of 400 V to 800 V, and thus different parameters than those shown in Table 2 can be used.

The high-side driving voltage and the low-side driving voltage can be mirrored and can be electrically isolated from one another. The high-side driving voltage may not appear in FIG. 3 to be electrically connected to other illustrated circuit elements, but the high-side driving voltage can be electrically connected as, for example, copper windings of an electrical transformer that also includes the low-side driving voltage as copper windings. For example, in the system 100 of FIG. 1, the high-side driving voltage of FIG. 3 can be configured to generate a first V_{CC} 112 for the first MOSFET 108, and the low-side voltage of FIG. 3 can be configured to generate a second V_{CC} 114 for the second MOSFET 110.

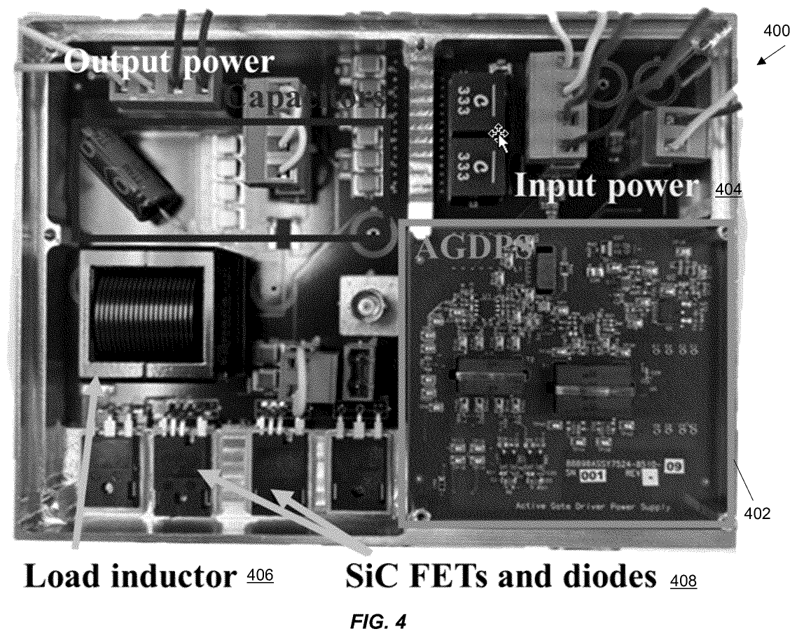

FIG. 4 illustrates one embodiment of the system 200 of FIG. 2 as a system 400 that can include a GDPS 402 and a power source 404 configured to supply power to the GDPS 402 according to some embodiments. As shown in FIG. 4, the system 400 can also include a load inductor 406 and SiC FETs and diodes 408.

The system 400 in this illustrated embodiment can include a synchronous buck converter (or a synchronous step-down converter, or a DC-DC converter to reduce a high input voltage to a low output voltage), with the analyzed SiC MOSFET described in relation to Table 2 as the primary switching device. The input voltage can, as in this illustrated embodiment, range up to 56 V to demonstrate a 28 V output, which is a common power rail for aerospace applications. The general selected duty cycle can, as in this illustrated embodiment, be 50% such that the output voltage can be halved and the input current can be doubled. The buck converter in this illustrated embodiment is configured to operate with a switching frequency of 50 kHz up to 250 kHz. As shown in FIG. 4, the system 400 can include a frame such that the two boards for the buck converter and the primary switching device can integrate seamlessly, and similarly to a final flight-grade board.

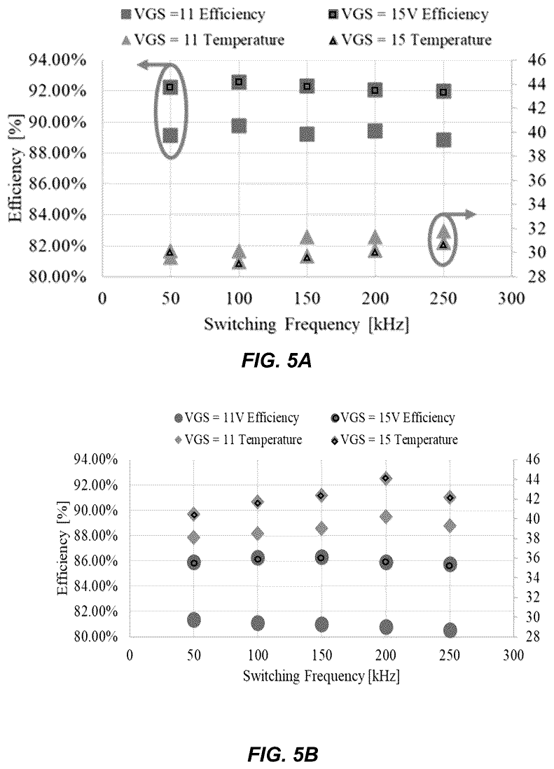

To demonstrate the overall changes in performance of the system 400 with only changing the gate voltage, experimental tests were conducted to measure the overall system efficiency at different switching frequencies, load currents, and static/external V_{GS} amplitudes (11 V and 15 V). Experimental tests were conducted with a 24 V input, and input current of 2.5 A, and 5 A (5 A and 10 A output). The switching frequency was swept between 50 kHz and 250 kHz. FIG. 5A is a graph showing measured efficiency and high-side transistor case temperature of the synchronous buck converter of FIG. 4 operating at varying switching frequency, different V_{GS} values, and 5 A output current. FIG. 5B is a graph showing measured efficiency and high-side transistor case temperature of the synchronous buck converter of FIG. 4 operating at varying switching frequency, different V_{GS} values, and 10 A output current.

It can be seen in FIGS. 5A and 5B that the synchronous converter operates as expected, with the overall decrease in efficiency as switching frequency increases. Additionally, a major shift can be seen between the 5 A and 10 A output current instances where the general efficiency when V_{GS}=11 V was around 89% at the 5 A load, and down towards 81% at the 10 A load. Similarly, the efficiency made a dramatic decrease with respect to output load when V_{GS}=15, however to a smaller degree. The efficiency dropped from roughly 92% towards 86%; only a 6% difference in comparison to an 8% difference. The changes can also be seen in FIGS. 5A and 5B, through the changes in the operating temperature of the high-side SiC MOSFET. In the 10 A load case alone, the temperature had a maximum of 44.1° C. when V_{GS}=11 V, where the maximum was only 40.2° C. when the V_{GS}=15 V. Considering the overall load power of this demonstration is not too demanding, this 4° C. delta shows the direct relationship and need for having the opportunity to increase the V_{GS} to the terrestrially rated value.

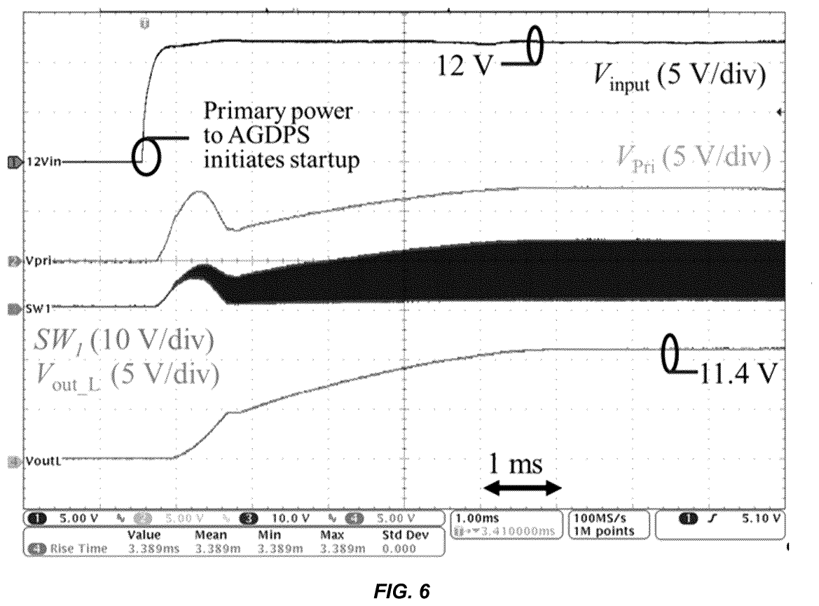

In the experimental test, the AGDPS 402 was then fully integrated with the buck converter and the startup routine was established and monitored before primary power was applied to the synchronous buck converter. The startup waveforms were recorded and are shown in FIG. 6. FIG. 6 shows one embodiment of a startup sequence of the AGDPS 402, when primary power was applied to the input voltage rail and output voltage was monitored to be 11.4 V. Once the primary input rail of the AGDPS 402 has an applied voltage, the circuit transitioned to output the low voltage magnitude, and after a few milliseconds the outputs for the low and high sides were measured to be approximately 11.2 V.

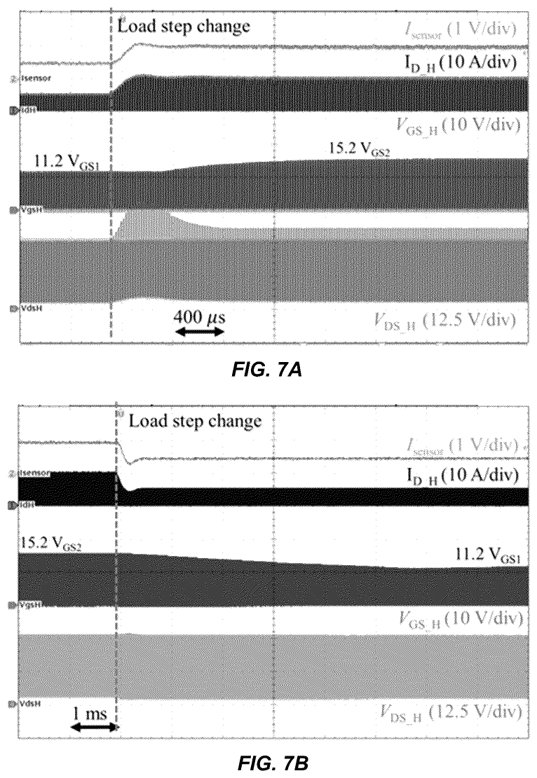

The synchronous buck converter was then tested with the integrated AGDPS 402 at 11 V, and the current sense loop was tuned and adjusted such that the transition point would be seen near the 10 A output current. FIGS. 7A and 7B are graphs showing the two switching waveforms of the AGDPS 402 as a load step up and down was applied to the synchronous buck converter. In particular, FIG. 7A shows output waveforms of the AGDPS 402 from a transition from a low-output state to a high-output state, and FIG. 7B shows output waveforms of the AGDPS 402 from a transition from the high-output state down to the low-output state. The buck converter was operating with a 24 V input and at 100 kHz, and the electronic load was set to sink 5 A and step to 10 A and back down to 5 A. The transition time seen in the step up shows a much faster transition time only needing approximately 1 ms of total time between the load step and the transition from 11 V to 15 V. FIG. 7B shows the impact of the hysteresis controller which monitors the load current and ensures that the current has decreased over the course of multiple switching events. To step the load down required nearly 6 ms of time in comparison to the 1 ms that was observed when the load current exceeded the threshold.

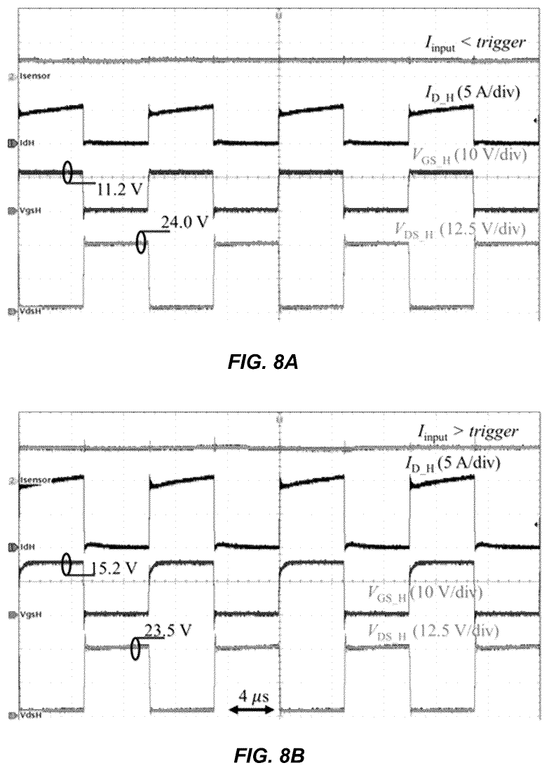

The switching waveforms from the operating synchronous buck converter of FIG. 4 at both V_{GS} values just before and just after the transition can be seen in FIGS. 8A and 8B. FIG. 8A is a graph showing output waveforms for the synchronous buck converter of FIG. 4, operating at 100 kHz when load current was below a current trigger (predetermined threshold current value) and V_{GS} equaled 11 V. FIG. 8B is a graph showing output waveforms for the synchronous buck converter of FIG. 4 operating at 100 kHz when the load current was above the current trigger (predetermined threshold current value) and V_{GS} equaled 15 V.

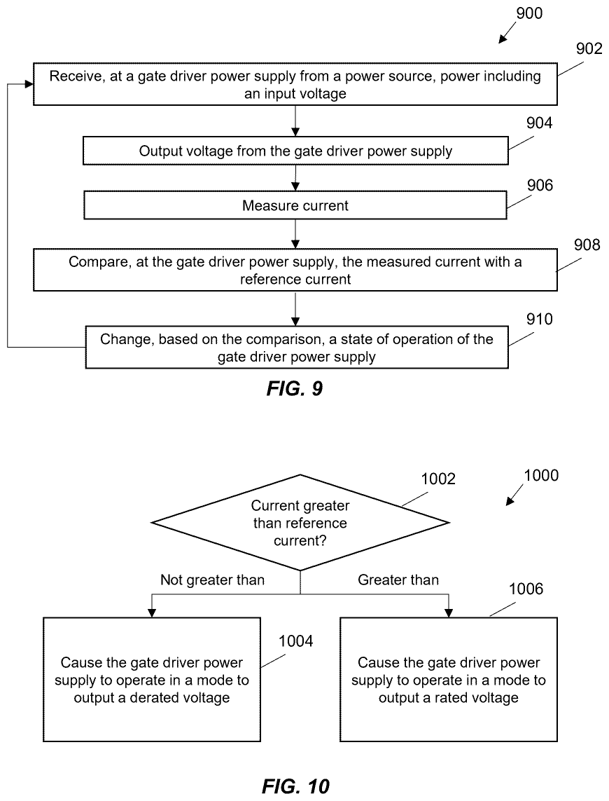

FIG. 9 illustrates a flowchart showing one embodiment of a method 900 for supplying power. The method 900 of FIG. 9 is described with respect to the system 200 of FIG. 2 for ease of explanation but can be performed similarly with other embodiments of systems. While an order of operations is indicated in FIG. 9 for illustrative purposes, the timing and ordering of such operations may vary where appropriate without negating the purpose and advantages of the examples set forth in detail herein.

The method 900 can include receiving 902, at the GDPS 202 from the power source 204, power including an input voltage, and the GDPS 204 outputting 904 a voltage. The output voltage can initially be a default output voltage. A current of the power circuit 209 can be measured 906, at the power circuit 209, using the current sensor 210. The measured 904 current can be communicated from the current sensor 210 to the controller 206.

The measured 906 current can be compared 908, at the GDPS 202 using the controller 206, with a reference current. The reference current can be stored in the memory 214 where the reference current can be accessed by the processor 212, which can perform the comparing 908.

The method 900 can also include changing 910, based on the comparison 908, a state of operation of the GDPS 202. As discussed further below with respect to FIG. 10, the GDPS 202 can be changed 910 between a first state of operation, in which the GDPS 202 can output a first output voltage, and a second state of operation, in which the GDPS 202 can output a second output voltage that can be different than the first output voltage. The second output voltage can be different than the first output voltage by the GDPS 202 changing its operating point. In this way, the GDPS 202 can operate in a state of operation that allows for achieving reliability and minimizing electrical losses.

As the power source 204 continues to provide power to the GDPS 202, the method 900 can repeat, with the state of operation of the GDPS 202 being changed 910 as needed when (and if) the measured 906 current indicates that such a change 910 is needed. In an aerospace application, for example, the GDPS 202 can operate in a derated state of operation a majority of the time, which can be 99% of the time, during a spacecraft mission and can operate in a high-performance state of operation in the remaining time, which can be 1% of the time, during the spacecraft mission, such as during liftoff. The derated voltage can thus be the default output voltage.

FIG. 10 illustrates a flowchart showing one embodiment of aspects of the method of FIG. 9. The method 1000 of FIG. 10 is described with respect to the system 200 of FIG. 2 and the GDPS 300 of FIG. 3 for ease of explanation but can be performed similarly with other embodiments of systems. While an order of operations is indicated in FIG. 10 for illustrative purposes, the timing and ordering of such operations may vary where appropriate without negating the purpose and advantages of the examples set forth in detail herein.

As shown in FIG. 10, the comparing 908 of the measured 906 current with the reference current can include determining 1002, using the controller 206 of the GDPS 202, whether the measured 906 current is less than the reference current. The reference current can represent a predetermined threshold operating current magnitude of the primary power circuit 209 indicative of when a high-performance state of operation is needed for optimal performance of the GDPS 202 in the particular application in which the GDPS 202 is being used.

If the measured 906 input current is determined 1002 to be less than the reference current, the GDPS 202, using the controller 206, can cause 1004 the GDPS 202 to operate in a mode to output a derated voltage. The GDPS 202 may already be outputting the derated voltage, in which case the output voltage does not change. If instead the GDPS 202 is outputting a rated voltage, the GDPS 202 can adjust the output voltage to be the derated voltage.

If the measured 906 current is determined 1002 to be greater than the reference current, the GDPS 202, using the controller 206, can cause 1006 the GDPS 202 to operate in a mode to output a rated voltage. The GDPS 202 may already be outputting the rated voltage, in which case the output voltage does not change. If instead the GDPS 202 is outputting the derated voltage, the GDPS 202 can adjust the output voltage to be the rated voltage. In this way, a higher voltage can be output from the GDPS 202 to allow for higher performance.

Certain embodiments are described to provide an overall understanding of the principles of the structure, function, manufacture, and use of the devices, systems, and methods disclosed herein. One or more examples of these embodiments are illustrated in the accompanying drawings. Those skilled in the art will understand that the devices, systems, and methods specifically described herein and illustrated in the accompanying drawings are non-limiting embodiments and that the scope of the present invention is defined solely by the claims. The features illustrated or described in connection with one exemplary embodiment may be combined with the features of other embodiments. Such modifications and variations are intended to be included within the scope of the present invention.

Further, in the present disclosure, like-named components of the embodiments generally have similar features, and thus within a particular embodiment each feature of each like-named component is not necessarily fully elaborated upon. Additionally, although specific features of various embodiments may be shown in some drawings and not in others, this is for convenience only. In accordance with the principles of the disclosure, any feature of a drawing may be referenced and/or claimed in combination with any feature of any other drawing.

A person skilled in the art will appreciate that a value may not be precisely at a value but nevertheless be considered to be about or substantially at that value for any of a number of reasons, such as manufacturing tolerances and/or sensitivity of measurement equipment.

One skilled in the art will appreciate further features and advantages of the devices, systems, and methods based on the above-described embodiments. Accordingly, this disclosure is not to be limited by what has been particularly shown and described, except as indicated by the appended claims. All publications and references cited herein are expressly incorporated herein by reference in their entirety for all purposes.

The present disclosure has been described above by way of example only within the context of the overall disclosure provided herein. It will be appreciated that modifications within the spirit and scope of the claims may be made without departing from the overall scope of the present disclosure.

What is claimed is:

1. A system for supplying power, comprising:
a gate driver power supply configured to:
receive an input voltage from a power source, and
change between a first state of operation, in which the gate driver power supply receives an input voltage having a voltage value from the power source and the gate driver power supply outputs a first output voltage, and a second state of operation, in which the gate driver power supply receives the input voltage having the voltage value from the power source and the gate driver power supply outputs a second output voltage, the second output voltage being different than the first output voltage;
wherein the gate driver power supply comprises a controller;
the controller is configured to:
compare a reference current data value with a current data value indicating a current in a power circuit, and
based on the comparison, cause the gate driver power supply to change from one of the first state of operation and the second state of operation to the other of the first state of operation and the second state of operation.

2. The system of claim 1, wherein the first output voltage is a rated voltage;
the second output voltage is a derated voltage;
the controller is further configured to cause the gate driver power supply to change from the first state of operation to the second state of operation based on the current data value being less than the reference current data value; and
the controller is further configured to cause the gate driver power supply to change from the second state of operation to the first state of operation based on the current data value being greater than the reference current data value.

3. The system of claim 1, further comprising the power source.

4. The system of claim 1, wherein the gate driver power supply further comprises:
a linear voltage regulator configured to receive the input voltage, and
a push-pull converter in-line with the linear voltage regulator.

5. The system of claim 4, wherein the controller being configured to cause the gate driver power supply to change from the one of the first state of operation and the second state of operation to the other of the first state of operation and the second state of operation based on the comparison comprises:
causing a bias of the linear voltage regulator to change.

6. The system of claim 1, wherein the power circuit comprises:
a first power transistor comprising silicon carbide, and
a second power transistor comprising silicon carbide.

7. The system of claim 1, further comprising a current sensor configured to measure the current in the power circuit.

8. The system of claim 7, wherein the power circuit includes the current sensor.

9. A system for supplying power, comprising:
a current sensor configured to measure a current in a power circuit; and
a gate driver power supply configured to output an output voltage, the gate driver power supply comprising:
a linear voltage regulator configured to receive a voltage input to the gate driver power supply from a power source,
a push-pull converter in-line with the linear voltage regulator, and
a controller configured to:
compare a reference current data value with a current data value indicating the measured current, and
based on the comparison, cause the gate driver power supply to change the output voltage.

10. The system of claim 9, wherein the output voltage is one of: a rated voltage or a derated voltage.

11. The system of claim 9, wherein the controller is further configured to cause the gate driver power supply to change from outputting a first output voltage to outputting a second, different output voltage based on the measured current data value being less than the reference current data value.

12. The system of claim 11, wherein the controller is further configured to, based on the comparison indicating the measured current data value being greater than the reference current data value, cause the gate driver power supply to change from outputting the second output voltage to outputting the first output voltage.

13. The system of claim 9, wherein the power circuit comprises:
a first power transistor comprising silicon carbide, and
a second power transistor comprising silicon carbide.

14. The system of claim 13, wherein the power circuit includes the current sensor.

15. The system of claim 9, further comprising the power source.

16. A method for supplying power, comprising:
determining, at a gate driver power supply, whether a current data value indicating a current in a power circuit is less than or greater than a reference current value;
if the current data value is determined to be less than the reference current value, causing the gate driver power supply to output a derated output voltage; and
if the current data value is determined to be greater than the reference current value, causing the gate driver power supply to output a rated output voltage.

17. The method of claim 16, further comprising measuring, at the power circuit, the current in the power circuit.

18. The method of claim 16, wherein:
a current sensor measures the current,
a linear voltage regulator of the gate driver power supply receives a voltage input to the gate driver power supply from power source,
a push-pull converter of the gate driver power supply is in-line with the linear voltage regulator, and
a controller is configured to perform the determining, the causing to output the derated output voltage, and the causing to output the rated output voltage.

19. The method of claim 18, wherein the power circuit includes the current sensor.

20. The method of claim 16, further comprising receiving, at the gate driver power supply, power from a power source;
wherein the determining, the causing of the gate driver power supply to output the derated output voltage, and the causing of the gate driver power supply to output the rated output voltage occur with the gate driver power supply receiving the power from the power source.
